(19) United States
(12) Patent Application Publication
(10) Pub. No.: US 2004/0155650 A1
(43) Pub. Date: Aug. 12, 2004

(54) Verification method

(76) Inventors: Andreas Plaas-Link, Schmallenberg (DE); Renaid Kroczek, Kluse (DE)

Correspondence Address: Reed Smith, Suite 1400, 3110 Fairview Park Drive, Falls Church, VA, 22042, US

(21) Appl. No.: 10/473,036

(22) PCT Filed: Mar. 26, 2002
(86) PCT No.: PCT/EP02/03362

(30) Foreign Application Priority Data
Mar. 26, 2001 (DE) 101 14 925.5

(51) Int. Cl. G01R 33/12; G07F 7/12; G06K 7/08

(52) U.S. Cl. 324/239; 324/228; 194/210; 235/449; 340/568.7; 340/572.1

(57) ABSTRACT

The invention relates to a method and a device for verifying valuable documents, in particular banknotes (5), labels, bonds, stamps or identification cards. Conventional methods involve a high percentage of errors. The aim of the invention is to provide a method for identifying banknotes, labels, bonds, stamps and identification cards, which allows a reliable and rapid identification of forgeries, whereby the identification and verification process is tolerant in relation to modification to the position of the valuable documents, in particular in relation to modifications to the distance. To achieve this, a valuable document is provided with an electromagnetically active structure (1), the valuable document is then exposed to an electromagnetic high-frequency field, the influence of the electromagnetic high-frequency field is measured through the valuable document and the measurement result is compared with reference data. The invention also relates to a device for carrying out said method.

The invention relates to a method and a device for verifying valuable documents, in particular banknotes, labels, bonds, stamps or identification cards.

Hitherto known methods, for example applied to verify banknotes, make use of the optical characteristics of the items to be verified, such as the transmission, absorption and reflection behavior; they compare the measured values to reference data and present the relevant verification results, i.e. provide information whether or not the checked item is genuine. All these methods have a great disadvantage in that they can only warrant a reliable verification if the position of the examined objects is always exactly the same during the verification process. These methods are therefore afflicted with a great number of errors involving both the rejection of genuine and the acceptance of forged banknotes. It has been this high error probability that disqualified the use of these methods for cash desks or counters.

Furthermore, another known detection method involves the magnetic properties of the ink used for banknote printing. In this case, an electromagnetic sensor records the magnetic pattern when the banknotes are passing over the sensing element. This method as well has an error rate of about 5% and for that reason is not suited for use with cash desks or counters. It is also sophisticated and expensive.

Due to the problems and drawbacks associated with the prior art it is the object of the present invention to provide a method for the recognition of valuable documents, in particular banknotes, labels, bonds, stamps and identification cards, that enables a reliable and quick detection of counterfeits with said identification and verification method being capable of tolerating changes in the position of the checked objects, especially distance variations.

According to the invention this objective is reached in that by the method mentioned above the valuable document is provided with an electromagnetically active structure, it is further exposed to an electromagnetic high-frequency field, the influence exerted by the valuable document on the electromagnetic high-frequency field is measured and the result of the measurement is compared to reference data.

It is, furthermore, the object of the invention to provide a device for carrying out said method, said device having at least one pair of antennae consisting of at least one transmitting antenna and one receiving antenna for the generation of a high-frequency field.

Advantageous further embodiments of the invention will arise from the subclaims.

The functionality of the measuring technology according to the invention involves the determination of the resonance frequency of a structure usable as an antenna in banknotes, labels, bonds, stamps and identification cards. For this purpose the transmitter is capable of generating right-hand circularly and left-hand circularly, horizontally or vertically polarized electromagnetic fields the frequency of which is modified until one or more resonances can be detected and allocated to certain frequencies.

When generating a high-frequency field in the case of resonance also phase shifting phenomena arise which are characteristic of the individual electromagnetically active structures and can thus be evaluated. With resonance arising the method makes use of the attenuation or gain of the field strength and/or modification of the phase position of the structure used as antenna on a receiver and compares it to reference setpoints predetermined for the electromagnetic structures incorporated into banknotes, labels, bonds, stamps and identification cards. The benefits that can be obtained through the invention encompass the possibility to determine very quickly the specific resonance frequencies of this structure serving as antenna and compare them to setpoints which are typical of electromagnetically active structures incorporated into banknotes, labels, bonds, stamps and identification cards.

Since frequencies of around 2 GHz are employed 10 measuring cycles per second can be achieved based on a frequency increase, for example, of 1.5 to 2.5 GHz in steps of 0.6 MHz und 100.00 sine oscillations per measurement. This enables a length determination accuracy of below 0.01 mm to be reached for a structure in the resonance range. Since the generation of a high-frequency field that changes its frequency periodically is quite simple and a broad-band receiver can also be set up quite easily the method may be implemented without difficulty and thus is a moderately priced solution. In case of banknotes electrically conductive security threads are as a rule incorporated which serve as passive antennae and can be measured with the aid of this method. Since the security threads in banknotes are usually of different length measuring the resonance frequencies enables a distinction to be made between banknotes. Furthermore, it can be reliably established whether a security thread is genuine or has merely been imprinted. An expedient further development provides for the integrated electromagnetically active structure 1 to be used similar to a reflector 4 or director 5 of an antenna and in this way influencing the dispersion characteristics of the transmitter 2 in a manner that is typical of the material, geometry and mechanical properties of the electromagnetically active structure 1. With this method an even better determination of the characteristics of the individual electromagnetically active structures 1 can be achieved by arranging several receiving antennae at different positions.

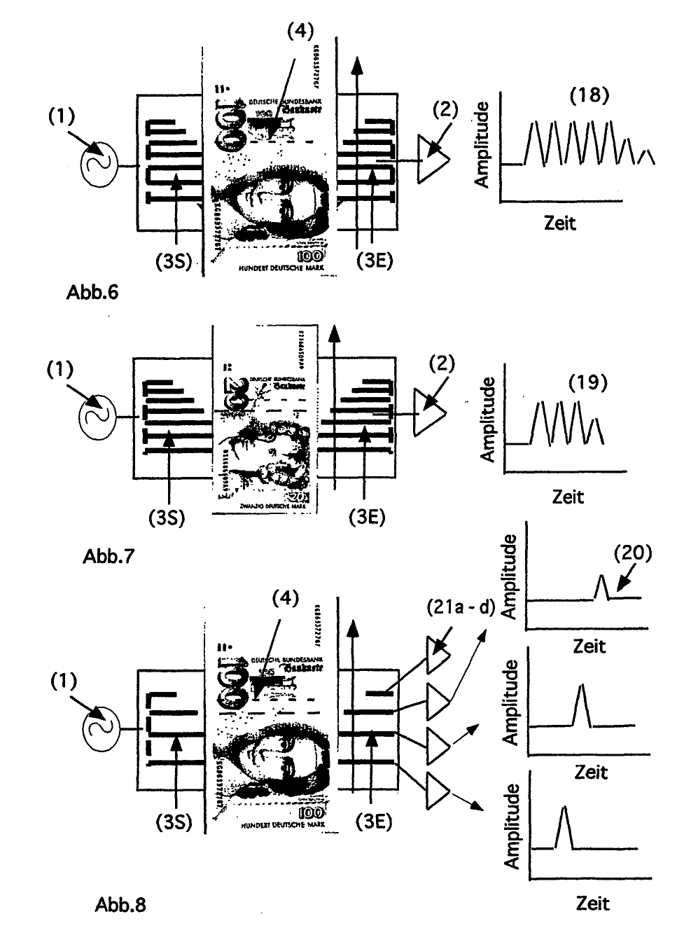

If the intensity of the field strength is high, the electromagnetically active structure heats up. This heat-up is measured by suitable sensors. Depending on the degree of such a heat-up of the electromagnetically active structure 1 it is possible to confirm and determine a state of resonance. The geometry and localization of the heat-up of the electromagnetically active structure during a state of resonance is as well characteristic of the type of such an electromagnetically active structure. This temperature rise and localization may also be measured and determined in a contactless fashion by means of infrared sensors 7, as shown in FIG. 4. The frequency of the high-frequency field is continuously passed through periodically from a minimum to a maximum value to establish a frequency spectrum by successively bringing the security threads of different banknotes to a state of resonance to enable in this way different banknotes to be distinguished (FIG. 7).

In the event bundled banknotes are to be processed it is also possible to determine by means of a single measurement the number of electromagnetically active structures due to the modification of the changed high-frequency field caused by bundling. This makes it possible to determine the number of banknotes. Furthermore, in the event of the resonances being determined sufficiently fast the banknotes may be quickly changed over enabling a counting operation to be performed. This allows money to be counted without the necessity of sorting beforehand a bundle of, for example, banknotes of dissimilar denomination.

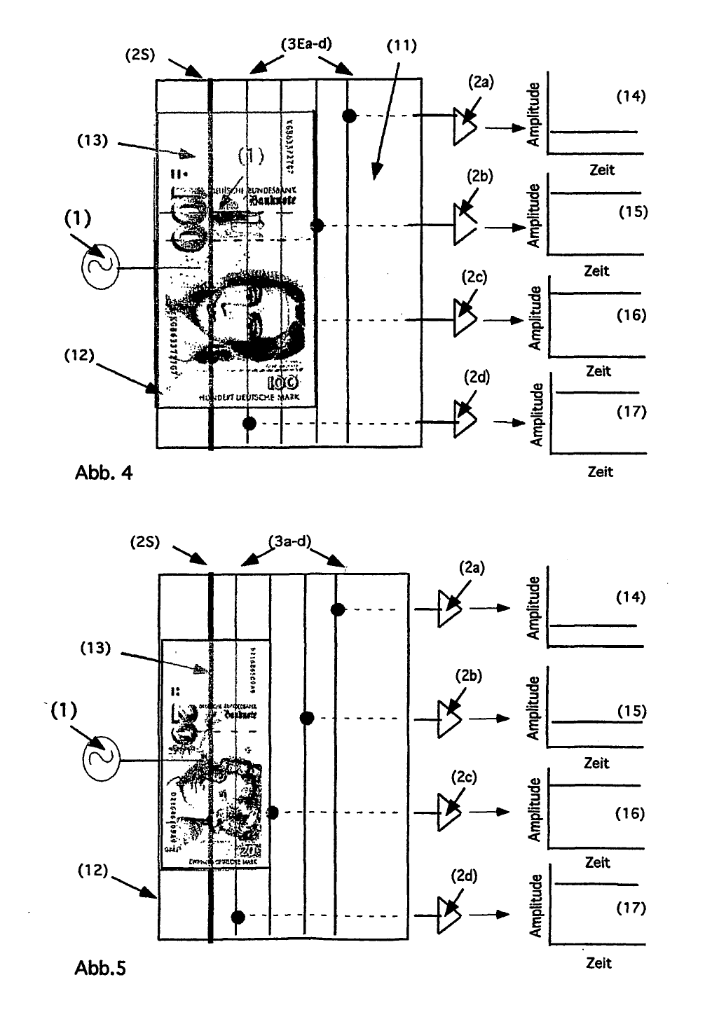

The method may also be implemented with the aid of a manual device (FIG. 5) which houses the arrangement. The method and, resp., the arrangement may also be incorporated into cash dispensers/cashpoints and goods vending machines. To indicate detected banknotes light emitting diodes, electrical outputs or displays may provide information about or output the value of the identified money.

Displacing the banknotes, labels, bonds, stamps and identification cards during the repeated determination of the resonance frequency in relation to the transmitter of the high-frequency field will cause the resonance spectrum to be changed as a function of the characteristics of the electromagnetically active structure which by making use of a combined evaluation method allows an additional discrimination of the measured structures.

Due to the fact that security threads in banknotes are not always arranged in the same position it is necessary to draw the banknotes past the transmitter and compare the various resonance bands so determined to those that have been established for genuine banknotes.

In the event the frequency spectrum of the individual banknotes, labels, bonds, stamps and identification cards is highly specific due to special geometry or materials involved, for examples in banknotes of the same denomination, this may be used as a fingerprint for identification.

In FIG. 8 such an individual distribution and amplitude of the resonances is shown.

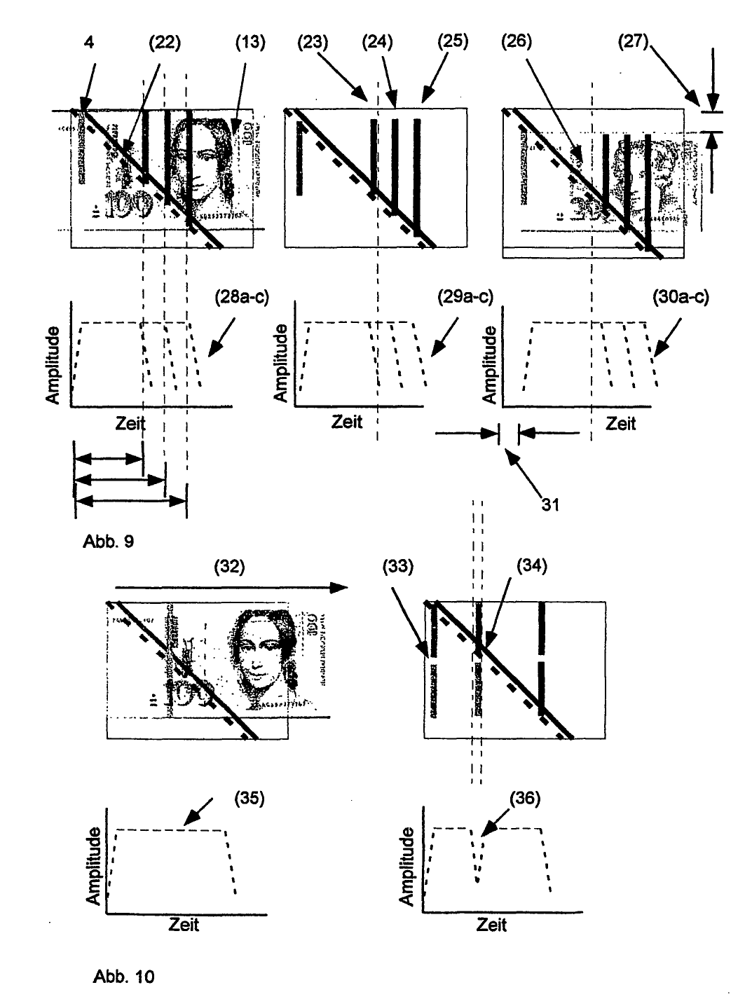

In case a single antenna is present in the form of an electromagnetically active structure only one spectrum would appear as shown in FIG. 9. In this case only the harmonic wavelengths would primarily be measured as spurious resonances. A simplified arrangement successively generates only those frequencies for which resonance is expected with the individual banknotes.

The device and the method for the verification of banknotes may also be employed for manual money acceptance and payout for the identification of the bills. This may be realized with the help of a hand unit or stationary device into or past which the banknotes, labels, bonds, stamps to be checked are inserted or drawn, respectively. It may be necessary in this case to increase the transmission energy.

The electromagnetically active structures 1 can be destroyed by overheating through the high intensity of a high-frequency field so that the banknotes, labels, bonds, stamps and identification cards are invalidated in this way. This is, for instance, of special interest if banknotes, labels, bonds, stamps and identification cards are found to have been counterfeited. In the case of stamps the method may also be employed to perform an automatic invalidation. Since the destruction is only possible under resonance conditions the electromagnetically active structure is only interrupted at a specific point. When examined during a subsequent verification check the resonance spectrum will have changed because the structures acting as antennae are shortened. In this way, a marker can be generated for a various goods, documents, letters etc.

This may, for example, indicate whether such goods, documents and letters have actually passed a check with interruption of the electromagnetically active structure. This marker may be applied so as to be visible or remain invisible.

To mark individual banknotes, labels, bonds, stamps and identification cards individually each single banknote, label, bond, stamp and identification card may comprise of a combination of different electromagnetically active structures.

These different electromagnetically active structures may consist of metal threads 9 of different length.

These metal threads of various lengths may be arranged so as to form different angles with each other. This would allow a further discrimination of the banknotes, labels, bonds, stamps.

In the event of labels the method enables merchandise planning and control systems to be controlled. To render the process of determining the frequency bands more independent of the positioning of the banknotes, labels, bonds, is stamps it is provided that the antennae, which for example are oriented as dipoles, generate electromagnetic fields simultaneously or successively at different angles that allow the resonance of the electromagnetically active structures to be determined independently of the position.

To render the process of identifying the banknotes, labels, bonds and stamps more independent with respect to changes in position within the generated high-frequency field it is provided that the transmitter generates both right-hand circularly and left-hand circularly, horizontally and/or vertically polarized electromagnetic fields.

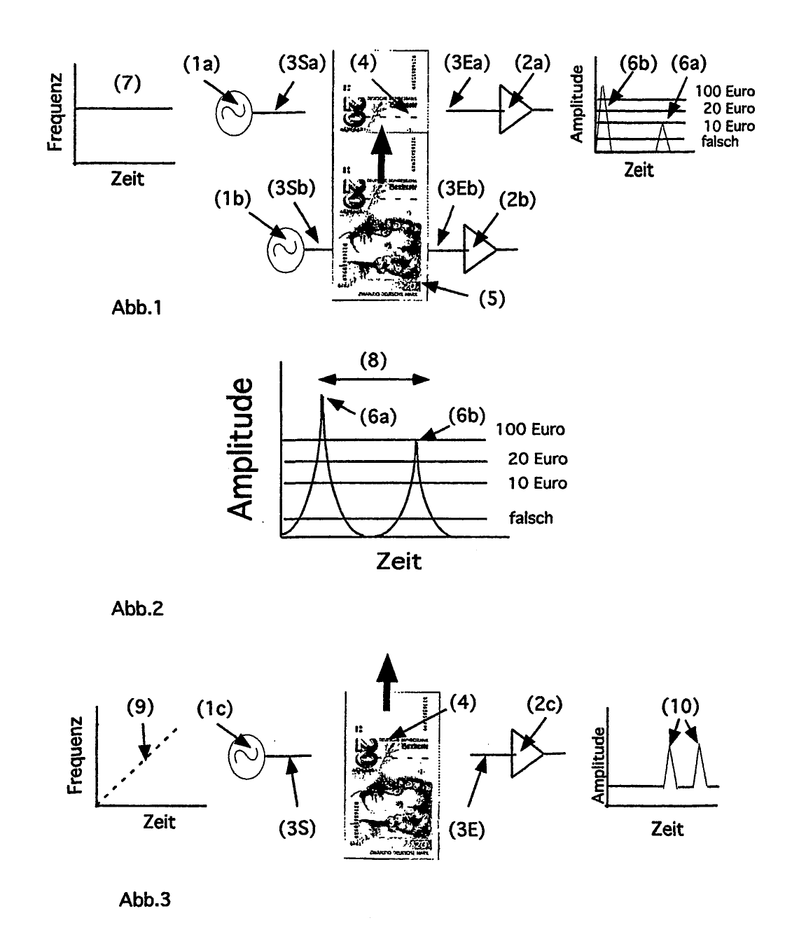

An embodiment of the invention is described below. A transmitter, FIG. 4, of low power is tuned at a frequency of 1.5 GHz-2.5 GHz. Using a VCO (voltage controlled oscillator) various frequencies are generated by producing a voltage of changing characteristic. The voltage is fed to the VCO in the form of a ramp, i.e. periodically, as a linearly ascending signal (FIG. 7). Depending on the control configuration the output signal coming from the VCO passes through the frequency band of 1.5 GHz-2.5 GHz. The output of the VCO generates a high-frequency field via an amplifier and an antenna (if necessary, a dipole). Opposite to this transmitter a broadband-type receiver is arranged at a distance of between 1 mm and 1 cm which measures the field strength of the high-frequency field. If an electromagnetically active structure (FIG. 1) is located between transmitter and receiver, resonance will be caused within this structure at certain frequencies or wavelengths. This will also give rise to a change, as a rule an attenuation, of the field strength detected by the receiver, or the signal is increased in the event of an inversion. This will be the case if the security thread of a banknote has a length that corresponds to the wavelength λ or λ/2 of the instantaneous frequency. In case of 100 measurements per 1 s in the GHz range an accuracy of the determination of the length of the security strip of below 1/10 mm can be attained if for the purpose of resonance determination 100,000 cycles are employed. If only 10,000 cycles or only 10 measurements per second are necessary the accuracy will be improved to values below 1/100 mm. In order to warrant the accuracy and consistency of the VCO a phase-locked loop arrangement is to be provided.

For resonance determination it is also possible to dispense with the receiver. In such a case, a method may be employed that originally was used for the determination of the correct antenna length for radio transmitters or radio receivers. For this purpose so-called grid dipmeters were used. A description of how this device functions can be found on the internet in a technical teaching provided by Technische Universität Clausthal of Nov. 27, 1994. Here it says basically: _{“}A dipper is a universal measuring instrument for taking comparative resonance measurements on oscillatory circuits”. A dipmeter consists of a variable-frequency oscillator having a calibrated frequency scale. In its original form as grid dipper the device operates in a simple oscillating circuit with a triode which provides for the current in the supply lead to the control grid to be indicated. To enable the resonance frequency of a circuit to be measured the dipper coil (which can usually be replaced to expand the frequency band) is coupled with the oscillating circuit coil of the circuit which shall be measured. The variable capacitor of the dipper is tuned until, when resonance occurs, the measured oscillating circuit draws energy from the dipper in which case the grid current decreases in the form of the characteristic ‘dip’. To enhance the accuracy the coupling should be as weak or loose as possible with the dip just being noticeable. Same as with an absorption-type frequency meter the measuring error is in the range of 2%. The following measurements may be performed with the help of a dipmeter: resonance measurements and adjustments of passive oscillating circuits in transmitters and receivers, resonance determination on antennae.

In conjunction with an inductance coil of known size the dipper may also be used as capacitance meter and together with a known capacitor also as inductance meter; furthermore, with the oscillator being switched off it may operate as absorption-type frequency meter. For further literature see publication FUNKAMATEUR 6/1998, page 693.

The benefits that can be obtained through the invention include the possibility to determine very quickly the specific coupling of this electromagnetically active structure (4) and compare it to setpoints which are typical of electromagnetically active structures incorporated into banknotes, labels, bonds, stamps and identification cards. A measurement of this security feature has not been taken hitherto and is to be seen as a cost-efficient and universally applicable means to verify the genuineness of banknotes, labels, bonds, stamps and identification cards. In the case of banknotes this electromagnetically active structure exists already and needs not be newly developed and introduced.

Preferably, the device and the method provide for the antenna of the transmitter (3S) and of the receiver (3E) to be spaced wider apart than the maximum length of the security strip (4) of a banknote (5).

This makes it possible that with a fixed frequency (7) the type and degree of the coupling and the influence on the high-frequency field (6b) between a receiver (1a) and a transmitter (2a) is indicative of the properties and length of the security strip (4).

This arrangement offers the advantage in that, through a simple transmitter, it can be detected on the receiver how long the security strip is and to what an extent the coupling effect between the antennae (3S and 3E) is improved through the security strip.

Preferably, the banknotes between the antennae (3Sa and 3Ea) shall be drawn through at known speed.

To be able to accurately measure the differences between the degree of coupling the invention provides that measuring the coupling effect (6a) between the antennae (3Sb and 3Eb) takes place before measuring the coupling between antennae (3Sa and 3Ea) so that the measurement between the antennae (3Sa und 3Ea) is taken after the signal (6a) has been measured and the time delay (8) expired, i.e. when the security strip (4) is exactly in correct position between the antennae (3Sa and 3Ea).

As a result of such a precise positioning of the safety strip between the antennae (3Sa and 3Ea) the repeatability of the measurements is significantly improved.

Due to the manufacturing technique employed with respect to the security strip (4) in banknotes these differ in a number of aspects from normal electric conductors.

Firstly, the ohmic resistance in the presence of direct voltage is as high as that of a nonconductor.

Secondly, resonance cannot be measured to the extent it can be detected in normal electric conductors.

Expediently, it has therefore been provided that certain incorporated electromagnetically active security strips (4) do not produce resonance (10) and that it can be ruled out that there is a proper security strip in the event resonance (10) is detected at λ/2 and λ.

In the event that only a minor coupling effect is detected between the antennae (3Sa and 3Ea) it has been provided in accordance with claim 9 that the presence of an intact security strip (4) is ruled out.

In the case of devices employed for a quick and primarily manual verification of banknotes it is proposed in accordance with claim 10 that the banknote (FIG. 4) is positioned at the edge (12) of a plate and that on this plate (11) a transmitting antenna (3S) is arranged with several receiving antennae (3Ea-d) being arranged parallelly to the edge (12) and spaced at various distances from it and with each of said receiving antennae being connected to one receiving amplifier each (2a-d), so that from the output signals (14,15,16,17) the denomination of the relevant banknote (13) to be examined can be derived.

To avoid faulty measuring results it is proposed to check with the help of a reflection measurement or transmission measurement whether the banknote has been correctly positioned at edge (12).

For the same reason it is proposed that an audible warning signal is given in the event of an incorrect position at edge (12).

The method and, resp., the arrangement may also be incorporated into cash dispensers/cashpoints and goods vending machines.

To indicate detected banknotes light emitting diodes, electrical outputs or displays may provide information about or output the value of the identified banknotes.

Preferably, the spacing between the transmitting (3S) and receiving antennae (3S) is great and is only bridged to some extent by the security thread. Therefore a wide dynamic range has to be bridged for the receiving amplifiers.

It will be expedient to draw the banknotes past several antennae (3a and 3b) arranged in parallel (FIG. 6). In this case the spacing between the transmitting antennae (3S) and the receiving antennae (3E) is different. In case the length of the security strip is equal to the distance between the transmitting and receiving antennae (FIG. 6, 3a and 3b) or if the strip extends beyond the transmitting and receiving antennae the coupling effect between the transmitter (1) and the receiver (2) will be maximum. From FIG. 6 (18) it can be seen that the 100 DM bill has been drawn past 5 antennae pairs and caused a maximum coupling effect to be signaled. As shown in FIG. 7 the security strip only spanned 3 antennae pairs and delivered only 3 peak values.

As illustrated in FIG. 8 the object is drawn past antennae pairs similar to those shown in FIGS. 6 and 7 but in this case time-wise singularized coupling peak values are produced that differ from those of the first coupling peak value only with respect to their time intervals, as described in claim 17.

It is also possible to draw the banknotes past a pair of antennae, as shown in FIG. 9. In this case, the banknote in accordance with claim 18 is drawn across a plate at a known speed and the transmitting and receiving antennae (22) are arranged obliquely and parallel (approximately 45) to the security strips (23,24,25). If the security strip covers the transmitting and receiving antennae (22) simultaneously a maximum coupling effect is produced and the high-frequency field influenced by the banknote, check card or identification card. The denomination of a banknote, i.e. the length of the security strip, can be recognized based on the time interval between the start of the covering and the end of the covering (28a-c).

This arrangement is advantageous in that the entire security strip is examined continuously in small increments to determine its properties and a signal (28a-c) is produced as shown in FIG. 9. Furthermore, the time period elapsing between the first coupling action and end of the coupling effect is not influenced by the spacing between banknote and the edge of plate (27).

Another advantage this arrangement offers is the possibility that interruptions in the security strip can be detected, as can be seen from the signal (36) in FIG. 10. In claim 19 it is therefore provided that the transmitting and receiving antennae (22) are arranged in parallel close to each other and that short segments of the security strip are examined successively and continuously and that in the event of an interruption (33) of the security strip such an interruption is detected (36). If only a single or just a few interruptions of the security strip are found these may be recognized by a suitable subsequently applied evaluation software system which may, for example, consider them to be negligible.

Another antennae configuration provides for the transmitting antennae, FIG. 13 (3S), to be arranged parallelly to edge 12 with only the receiving antenna (3E) in plate 11 being obliquely positioned to it (at approximately 45°).

With this arrangement the coupling effect between transmitting and receiving antennae is minimal in the absence of banknotes which means there is a more pronounced signal that can be measured when a security strip is present.

Changes of the coupling effect between the transmitting antenna (3S) and receiving antenna (3E) can be determined from the configuration of the security strip in or on the banknote. In this way the length of the segment of the security strip arranged on the outside or inside can be determined. Since the length of this spacing varies with the denomination of the banknote this measurement may be used to distinguish the individual banknotes even further.

The use of this procedure will ensure that genuine banknotes are not unnecessarily rejected. In this way and as set forth in claim 22 the method is, for is example, also suitable for the reliable counting of banknotes. Moreover, also the rejection or acceptance of banknotes/bills in goods vending machines or cash dispensers/cashpoints can thus be realized in a secure and simple manner.

Of course, all the previously described options intended to determine the properties and length of security strips may also be implemented in the manual acceptance of banknotes. An arrangement as detailed in FIG. 4 is particularly expedient for this purpose. In the event bills are accepted manually a mechanical feeder is not considered suitable due to the rather complicated feeding operation involved.

Another possible form of detecting/examining the properties of the security strip is to feed back the signal from the receiver to the transmitter so that an oscillatory circuit is obtained which is influenced by the coupling effect established via the security strip after suitably selected inductances/capacitances have been blended in. Changes of the oscillating frequency caused by variations of the coupling effect of the antennae via the security strip can be evaluated with the aid of a frequency-voltage converter.

When integrating the electromagnetically active structure into a closed oscillating circuit, aside from frequency changes also phase changes will arise depending on the coupling characteristics between transmitter and receiver.

The method of verifying the properties of a security strip with the help of a high-frequency field can also be realized by means of a hand device.

An embodiment of the invention is described below.

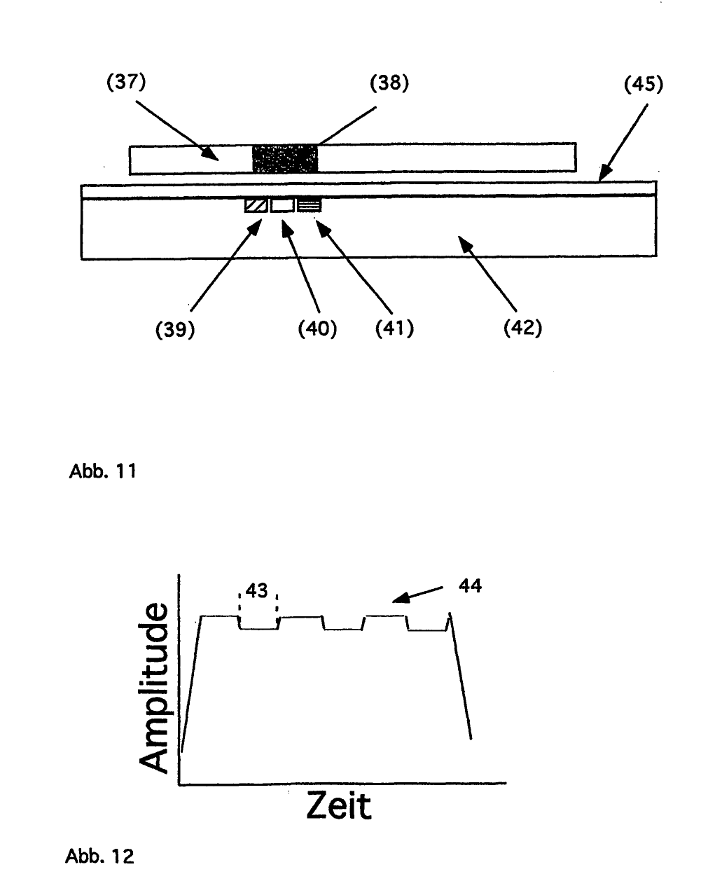

Two antennae (22) are etched into a printed-circuit (PC) board arranged at an angle of 45° to the edge of the PC board, FIG. 9. The spacing between the two antennae amounts to 1 mm, FIG. 11, (39) and (41). Between the 0.2 mm wide antennae (39,41) a shielding element has been arranged in the form of a conductor (40) connected to the ground. Onto the printed-circuit board a thin, non-conductive spacer element (45) is placed across which the security strip is moved.

As illustrated in FIG. 12, the signal (43, 44) is indicative of the length of the individual segments located in the paper of the banknote or on the paper of the banknote. The overall length of the signal with a high coupling factor is proportional to the length of the security strip.

1. Method for the verification of valuable documents, in particular banknotes (5), labels, bonds, stamps or identification cards, characterized in that,
the valuable document is provided with an electromagnetically active structure (1),
the valuable document is exposed to an electromagnetic high-frequency field,
the influence exerted by the valuable document on the electromagnetic high-frequency field is measured,
the result of the measurement is compared to stored reference data.

2. Method according to claim 1, characterized in that the electromagnetically active structure (1) is integrated into the valuable document.

3. Method according to claim 2, characterized in that the electromagnetically active structure (1) is a metallic security strip or metal thread (9) integrated into a banknote (5).

4. Method according to claim 1, characterized in that a pulsed high-frequency field is provided.

5. Method according to claim 1, characterized in that the frequency of the high-frequency field is increased incrementally.

6. Method according to at least one of the above claims, characterized in that the frequency of approximately 1.5 GHz is increased to approximately 2.5 GHz in steps of approximately 0.6 MHz.

7. Method according to at least one of the above claims, characterized in that the high-frequency field is produced by means of at least one antenna of a transmitter (3Sa) and by means of at least one antenna of a receiver (3Ea), with the distance between the antenna of the transmitter (3Sa) and the antenna of the receiver (3Ea) being greater than the span/reach of the electromagnetically active structure (1) in this direction during the verification process.

8. Method according to at least one of the above claims, characterized in that the valuable document passes between the antennae of the transmitter and receiver at a known speed.

9. Method according to at least one of the above claims, characterized in that at least two pairs of antennae each consisting of at least one receiver and at least one transmitter are arranged in succession in the direction of valuable document movement, and the measurement takes place at the antenna pair subsequently arranged in the direction of movement at a defined time interval after the electromagnetically active location provided in the valuable document has passed a the preceding pair of antennae.

10. Method according to at least one of the above claims, characterized in that an electromagnetic oscillatory circuit is produced in conjunction with the electromagnetic structure (1) of the valuable document, said circuit being excited at, at least, one defined frequency, and with the resulting oscillation amplitude being used as evaluation criterion to obtain the result of the verification of the valuable document based on a comparison with reference data.

11. Method according to claim 10, characterized in that the presence of an appropriate security strip is ruled out if the electromagnetic excitation does not produced a state of resonance.

12. Method according to at least one of the above claims, characterized in that the presence of an intact security strip is ruled out in the event the high-frequency field is only slightly affected electromagnetically through the electromagnetically active structure (1) of the valuable document.

13. Method according to at least one of the above claims, characterized in that during the verification process the valuable document is moved along a guiding element.

14. Method according to at least one of the above claims, characterized in that
the valuable document is moved along a plane surface provided with a longitudinal edge extending in the direction of valuable document movement, said surface being provided with at least one transmitting antenna,
several receiving antennae being arranged in parallel to the edge at various distances from said edge and each antenna being connected with a receiving amplifier each, and
the evaluation of the output signals being compared to reference data of valuable documents.

15. Method according to claim 13 or 14, characterized in that it is checked with the help of a reflection or transmission measurement whether the valuable document is guided along the guide element.

16. Method according to claim 15, characterized in that the result of the reflection measurement or transmission measurement is compared to a reference value and an optical or audible warning signal is produced if a defined deviation is exceeded.

17. Method according to at least one of the above claims, characterized in that the user is informed about the result of the valuable document verification process by means of an optical, acoustical or electronic output.

18. Method according to at least one of the above claims, characterized in that
several pairs of antennae (3), each consisting of at least one transmitter (2) and at least one receiver, are arranged on a verification device,
the distances in each case between receiving antennae (3e) and the respective transmitting antennae (3s) assigned to them in the individual antennae pairs differ,
the valuable document is guided sequentially along the individual pairs of antennae,
the influence exerted on the high-frequency field is measured in each individual case
the coupling effect produced by the electromagnetically active structure (1) of the valuable document and acting on the individual antennae pairs is compared between the different antennae pairs, and
the measured value of the antennae pair with maximum coupling between transmitter and receiver is compared to reference data.

19. Method according to claim 18, characterized in that by the spacing between transmitter and receiver of the antennae pair with maximum coupling effect the span/reach of the electromagnetically active structure (1) of the valuable document in the direction of the spacing is determined,
the span/reach of the electromagnetically active structure (1) is compared with reference data
and a conclusion is drawn as to the identity of the valuable document or type of valuable document.

20. Method according to claim 18, characterized in that the individual pairs of antennae are arranged in parallel with each other.

21. Method according to claim 18, characterized in that the individual pairs of antennae are not directly electrically connected with each other.

22. Method according to at least one of the above claims, characterized in that
the valuable document is moved at a known speed,
at least one antenna of a pair of antennae is arranged obliquely to the direction of movement of the maximum longitudinal span/reach of the electromagnetically active structure (1) of the valuable document,
the duration of maximum influence exerted on the high-frequency field by the electromagnetically active structure (1) of the valuable document is measured,
the duration is compared to reference data, and
based on the result of such comparison conclusions are drawn as to the identity of the valuable document or type of valuable document.

23. Method according to claim 22, characterized in that transmitter (2) and receiver of a pair of antennae are of longitudinal shape and arranged parallelly with each other and obliquely to the maximum longitudinal span of the electromagnetically active structure (1) of the valuable document.

24. Method according to claim 22, characterized in that one antenna of the antenna pair is arranged parallel to the direction of movement of the maximum longitudinal span of the electromagnetically active structure (1) of the valuable document whereas the other antenna of this antenna pair is positioned obliquely to it.

25. Method according to one of the claims 22 to 24, characterized in that the characteristics of the influence exerted through the electromagnetically active structure (1) of the valuable document on the high-frequency field are measured during the movement of the valuable document and compared with reference data either simultaneously or subsequently.

26. Method according to at least one of the above claims, characterized in that the valuable documents are banknotes (5) and said banknotes are identified and/or counted according to their denomination and/or type.

27. Method according to at least one of the above claims, characterized in that said method is part of a money dispensing or goods issuing process in an automated machine.

28. Method according to at least one of the above claims, characterized in that
in at least one pair of antennae the receiver is provided with a feedback feature to the transmitter (2),
inductances and/or capacitances are arranged in parallel and/or series with it, and
an oscillatory circuit is formed in this way,
into which the electromagnetically active structure (1) of the valuable document has been integrated.

29. Method according to claim 28, characterized in that the oscillatory circuit is excited and
the heat-up of the electromagnetically active structure (1) is measured.

30. Method according to claim 29, characterized in that the heat-up of the electromagnetically active structure (1) is detected in a contactless fashion by means of infrared sensors (7) and/or measured to determine its extent.

31. Method according to at least one of the claims 25 to 27, characterized in that the excitation frequency of the oscillatory circuit is varied during the valuable document verification process and the resonance frequencies are determined in this manner.

32. Method according to at least one of the above claims, characterized in that
the electromagnetically active structure (1) of the valuable document as part of an oscillatory circuit is excited simultaneously or successively,
the position of the resonance frequencies of the electromagnetically active structure (1) of the valuable document is determined,
the measuring results are compared to reference data.

33. Method according to at least one of the above claims, characterized in that
the electromagnetically active structure (1) of the valuable document located at different angles to pairs of antennae as part of an oscillatory circuit is excited simultaneously or successively,
the position of the resonance frequencies of the electromagnetically active structure (1) of the valuable document is determined,
the intensity of the resonance as a function of the angle position is measured and
the measuring results are compared to reference data.

34. Method according to at least one of the above claims, characterized in that the electromagnetically active structure (1) of the valuable document is excited by the high-frequency field to such an extent that it is destroyed.

35. Method according to at least one of the above claims, characterized in that
the combination (9) of various electromagnetically active structures (1) or the longitudinal span/reach of the electromagnetically active structure (1) or
the positioning angle of the electromagnetically active structure (1) to pairs of antennae
is detected by comparing the measurement to reference data, and
the valuable document or the type of valuable document is identified in this fashion.

36. Method according to at least one of the above claims, characterized in that the transmitter (2) generates right-hand circularly and/or left-hand circularly, and/or horizontally and/or vertically polarized electromagnetic fields.

37. Device for the verification of valuable documents, in particular banknotes (5), labels, bonds, stamps or identification cards as per the method according to at least one of the above claims, characterized in that said device comprises of at least one pair of antennae consisting of at least one transmitting antenna and one receiving antenna for the generation of a high-frequency field.

38. Device according to at least one of the above claims, characterized in that the distance between the antenna of the transmitter (3Sa) and the antenna of the receiver (3Ea) is greater than the span/reach of the electromagnetically active structure (1) in this direction during the verification process.

39. Device according to at least one of the above claims, characterized in that the device is provided with a drive system that moves the valuable document between the antennae of the transmitter and receiver at a defined speed.

40. Device according to at least one of the above claims, characterized in that at least two pairs of antennae each consisting of at least one receiver and at least one transmitter are arranged one after the other in the direction of valuable document movement.

41. Device according to at least one of the above claims, characterized in that an electromagnetic oscillatory circuit is produced in conjunction with the electromagnetic structure (1) of the valuable document, said circuit being excited at, at least, one defined frequency, and with the resulting oscillation amplitude being used as evaluation criterion to obtain the result of the verification of the valuable document based on a comparison with reference data.

42. The device method according to at least one of the above claims, characterized in that the device is provided with a guiding element along which the valuable document is moved during the verification process.

43. The device method according to at least one of the above claims, characterized in that the device has a plane surface along which the valuable document is moved, said surface being provided with a longitudinal edge extending in the direction of valuable document movement and also being provided with at least one transmitting antenna, several receiving antennae arranged in parallel to the edge at various distances from said edge and each antenna being connected with a receiving amplifier each.

44. Device according to claim 42 or 43, characterized in that the device has optical and/or acoustical warning devices by means of which an incorrect guidance of the valuable document in the device is signaled via an optical or acoustical alarm and/or the user is informed of the result of the valuable document verification process.

45. Device according to at least one of the above claims, characterized in that several pairs of antennae (3), each consisting of at least one transmitter (2) and at least one receiver, are arranged on the device, and the distances in each case between receiving antennae (3e) and the respective transmitting antennae (3s) assigned to them in the individual antennae pairs differ.

46. Device according to claim 45, characterized in that the individual pairs of antennae are arranged in parallel with each other.

47. Device according to claim 45, characterized in that the individual pairs of antennae are not directly electrically connected with each other.

48. Device according to at least one of the above claims, characterized in that the device is provided with a drive system that moves the valuable document between the antennae of the transmitter and receiver at a defined speed and at least one antenna of a pair of antennae is arranged obliquely to the direction of movement of the maximum longitudinal span/reach of the electromagnetically active structure (1) of the valuable document.

49. Device according to claim 48, characterized in that transmitter (2) and receiver of a pair of antennae are of longitudinal shape and arranged parallelly with each other and obliquely to the maximum longitudinal span of the electromagnetically active structure (1) of the valuable document.

50. Device according to claim 48, characterized in that one antenna of the antenna pair is arranged parallel to the direction of movement of the maximum longitudinal span of the electromagnetically active structure (1) of the valuable document whereas the other antenna of this antenna pair is positioned obliquely to it.

51. Device according to at least one of the above claims, characterized in that said device is part of an automated machine for money dispensing or goods issuing.

52. Device according to at least one of the above claims, characterized in that in at least one pair of antennae the receiver is provided with a feedback feature to the transmitter (2), inductances and/or capacitances are arranged in parallel and/or series with it, an oscillatory circuit is formed in this way into which the electromagnetically active structure (1) of the valuable document has been integrated.

53. Device according to claim 52, characterized in that the oscillatory circuit is excited and
the heat-up of the electromagnetically active structure (1) is measured.

54. Device according to claim 53, characterized in that the verification space is provided with at least one infrared sensor (7) which in a contactless manner detects and/or measures the magnitude of the heat-up of the electromagnetically active structure (1) by means of infrared sensors (7).

55. Device according to at least one of the above claims, characterized in that pairs of antennae are arranged offset in the verification space at defined angles to each other.
